(19) United States
(12) Patent Application Publication
(10) Pub. No.: US 2026/0016750 A1
(43) Pub. Date: Jan. 15, 2026

(54) SEMICONDUCTOR PHOTORESIST COMPOSITION AND METHOD OF FORMING PATTERNS USING THE COMPOSITION

(71) Applicant: Samsung Electronics Co., Ltd., Suwon-si (KR)

(72) Inventor: Hyun-Ji SONG, Suwon-si (KR)

(73) Assignee: Samsung Electronics Co., Ltd., Suwon-si (KR)

(21) Appl. No.: 19/061,141

(22) Filed: Feb. 24, 2025

(30) Foreign Application Priority Data
Jul. 12, 2024 (KR) 10-2024-0092418

(51) Int. Cl. G03F 7/039; G03F 7/20

(52) U.S. Cl. CPC G03F 7/0392; G03F 7/20

(57) ABSTRACT

Disclosed are a semiconductor photoresist composition and a method of forming patterns using the same, the semiconductor photoresist composition including a compound including at least one structural unit including an acyl azide functional group; and a solvent.

### CROSS-REFERENCE TO RELATED APPLICATION

This application claims priority to and the benefit of Korean Patent Application No. 10-2024-0092418 filed in the Korean Intellectual Property Office on Jul. 12, 2024, the entire contents of which are incorporated herein by reference.

### BACKGROUND OF THE INVENTION

### (a) Field of the Invention

This disclosure relates to a semiconductor photoresist composition and a method of forming patterns using the same.

### (b) Description of the Related Art

With the rapid spread of information media, functions of semiconductor devices are also developing rapidly. In recent semiconductor products, higher integration of products is beneficial to ensure competitiveness, lower costs, and/or higher quality. To achieve high integration, semiconductor devices are being scaled down.

As the integration of semiconductor devices increases, design rules for the components of semiconductor devices are decreasing. In manufacturing semiconductor devices including fine patterns in response to the trend toward high integration of semiconductor devices, it is required to implement patterns having fine line widths that exceed the resolution limits of photolithography equipment.

Meanwhile, in order to implement a semiconductor pattern with a fine line width, the photoresist layer should also be implemented with a photoresist pattern with a fine line width, and the LCDU (Local CD uniformity) of the photoresist pattern should be secured, and LER (Line Edge Roughness) and LWR (Line Width Roughness) should be improved.

Currently, efforts to satisfy insufficient characteristics of traditional chemically amplified (CA) photoresists such as a resolution, a photospeed, and feature roughness (or also referred to as a line edge roughness or LER) for the next generation device are being made.

An intrinsic image blurring due to an acid catalyzed reaction in these polymer-type photoresists limits a resolution in small feature sizes, which has been well known in electron beam (e-beam) lithography for a long time. The chemically amplified (CA) photoresists are designed for high sensitivity, but since their typical elemental compositions reduce light absorbance of the photoresists at a wavelength of 13.5 nanometers (nm) and thus decrease their sensitivity, the chemically amplified (CA) photoresists may partially have more difficulties under an EUV exposure.

CA photoresists can also suffer from roughness issues at small feature sizes, and experimentally have shown that the critical dimension uniformity (CDU), represented by line edge roughness (LER), increases with increasing diffusion distance of the acid-catalyzed photo acid, partly due to the nature of acid-catalyzed processes. Due to the defects and problems of CA photoresists, new types of high-performance photoresists are being explored.

### SUMMARY OF THE INVENTION

One aspect of the present disclosure provides a semiconductor photoresist composition configured to form a resist pattern having excellent resolution and developability.

Another embodiment provides a method of forming patterns with improved resolution and CDU by using the semiconductor photoresist composition and developing with an acidic aqueous solution.

A semiconductor photoresist composition according to one aspect of the present disclosure includes a compound including at least one structural unit including an acyl azide functional group; and a solvent.

According to another aspect of the present disclosure, a method of forming patterns includes forming an etching-objective layer on a substrate; forming a photoresist layer by coating a semiconductor photoresist composition on the etching-objective layer; forming a photoresist pattern in the photoresist layer by exposing and developing the photoresist layer; and etching the etching-objective layer using the photoresist pattern as an etching mask, wherein the semiconductor photoresist composition comprises a solvent and a compound including a structural unit including at least one acyl azide functional group.

A resist pattern applied with a resist composition according to one embodiment of the present disclosure blocks chemical blur caused by photo acid diffusion, which is a disadvantage of conventional chemically amplified resists, and uses an acidic aqueous solution when removing an exposed region, so swelling that occurs in conventional alkaline or organic developers is reduced, enabling formation of a high-resolution pattern.

### BRIEF DESCRIPTION OF THE DRAWINGS

FIGS. 1 to 5 are cross-sectional views for explaining a method of forming patterns using a semiconductor photoresist composition according to some example embodiments.

FIG. 6A is a schematic view explaining the mechanism by which chemical blur due to acid catalyst diffusion and swelling due to alkaline developer occur in a comparative example.

FIG. 6B is a schematic view for explaining a mechanism by which chemical blur is blocked and swelling is suppressed due to an acidic developer, unlike the comparative example, in an embodiment of the present disclosure.

### DETAILED DESCRIPTION OF THE EMBODIMENTS

Hereinafter, referring to the drawings, embodiments of the present disclosure are described in detail. In the following description of the present disclosure, the well-known functions or constructions will not be described in order to clarify the present disclosure.

In order to clearly illustrate the present disclosure, the description and relationships are omitted, and throughout the disclosure, the same or similar configuration elements are designated by the same reference numerals. Also, since the size and thickness of each configuration shown in the drawing are shown for better understanding and ease of description, the present disclosure is not necessarily limited thereto.

More specifically, in the drawings, the thickness of layers, films, panels, regions, etc., may be exaggerated for clarity. In the drawings, the thickness of a part of layers or regions, etc., is exaggerated for clarity. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry. Additionally, whenever a range of values is enumerated, the range includes all values within the range as if recorded explicitly clearly, and may further include the boundaries of the range. Accordingly, a range indicated as “X” to “Y” and/or “between” “X” to “Y” includes all values between X and Y, including X and Y. It will also be understood that when an element such as a layer, film, region, or substrate is referred to as being “on” another element, it can be directly on the other element or intervening elements may also be present. Additionally, spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly.

As used herein, “substituted” refers to replacement of a hydrogen atom by a substituent (deuterium, a halogen, a hydroxy group, a cyano group, a nitro group, —NRR′ (wherein, R and R′ are each independently hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), —SiRR′R″ (wherein, R, R′, and R″ are each independently hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, or a combination thereof). “Unsubstituted” refers to non-replacement of a hydrogen atom by a substituent and the remaining of the hydrogen atom.

As used herein, when a definition is not otherwise provided, “alkyl group” refers to a linear or branched aliphatic hydrocarbon group. The alkyl group may be a “saturated alkyl group” (without any double bond or triple bond).

The alkyl group may be a C1 to C8 alkyl group. For example, the alkyl group may be a C1 to C7 alkyl group, a C1 to C6 alkyl group, a C1 to C5 alkyl group, or a C1 to C4 alkyl group. For example, the C1 to C5 alkyl group may be a methyl group, an ethyl group, a propyl group, an isopropyl group, an n-butyl group, an isobutyl group, a sec-butyl group, or a tert-butyl group, 2,2-dimethylpropyl group.

As used herein, “aryl group” refers to a substituent in which all atoms in the cyclic substituent have a p-orbital and these p-orbitals are conjugated and may include a monocyclic or fused ring polycyclic functional group (e.g., rings sharing adjacent pairs of carbon atoms) functional group.

As used herein, unless otherwise defined, “alkenyl group” refers to an aliphatic unsaturated alkenyl group including at least one double bond as a linear or branched aliphatic hydrocarbon group.

Hereinafter, a semiconductor photoresist composition according to some example embodiments is described.

The semiconductor photoresist composition according to an embodiment of the present disclosure includes a solvent and a compound including at least one structural unit including an acyl azide functional group.

The semiconductor photoresist composition may be a non-chemically amplified photoresist.

In general, chemically amplified photoresists are prepared by blending a polymer having a structure that is sensitive to acid together with a photoacid generator as the main component.

Chemical amplification refers to the phenomenon in which an active species generated by the action of a photon causes a chain of chemical reactions, resulting in a large amplification of the quantum yield. In comparative chemically amplified photoresists, acid is generated from a photoacid generator upon irradiation with light, and a chemical bond decomposition reaction (deprotection of acid-labile protection group of polymer) of the acid-reactive polymer occurs during the post-exposure bake (PEB) process by the chemical action of the acid. The acid present in the exposed region due to the heat energy transferred in the PEB step acts as a catalyst for the decomposition of the acid-reactive functional group (acid-labile protection group) of the polymer, amplifying the chemical reaction and causing a difference in solubility of the developer between the exposed region and the non-exposed region.

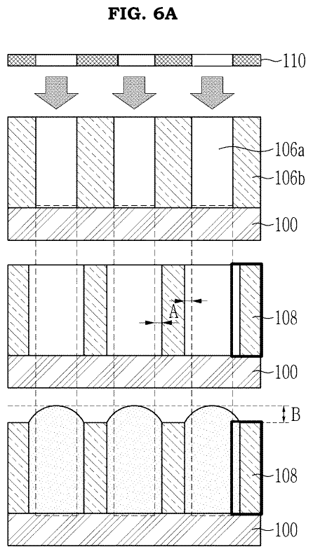

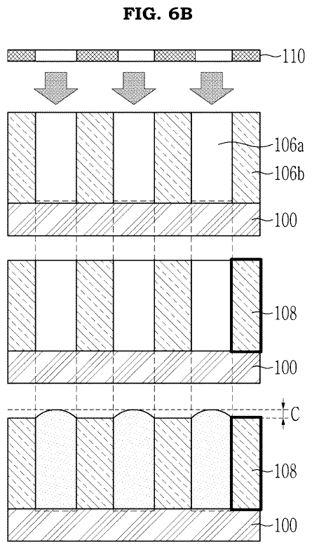

However, as explained in the schematic view of FIG. 6A, the acid generated in the exposed region does not remain only in the exposed region, but diffuses (A) to the non-exposed region during the time when heat is applied after exposure (post exposure bake). Accordingly, line width roughness increases and chemical blur (which causes a widening phenomenon between patterns) may occur.

In addition, the acid on the photoresist surface may be neutralized by alkali chemical species in the atmosphere (for example, NH₃, etc.), which may deteriorate the reactivity, or in severe cases, a poorly soluble layer may be formed on the surface, which may make the pattern profile non-uniform.

In contrast, the photoresist composition according to the present disclosure is a non-chemically amplified (Non-CAR) photoresist, which does not include a photoacid generator, such that a chain chemical reaction due to the chemical reaction of the acid does not occur, and therefore, as explained in the schematic view of FIG. 6B, there is no need for a post exposure bake time for applying heat after exposure, and even if it goes through PEB, there is no acid catalyst that diffuses to the non-exposed region. Accordingly, chemical blur can be fundamentally blocked, so that resolution and the critical dimension uniformity (CDU) on substrate may be improved.

The photoresist composition includes a compound comprising a structural unit represented by Chemical Formula 1.

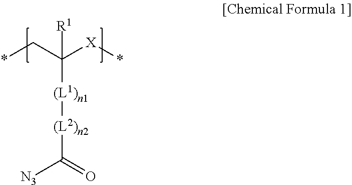

In Chemical Formula 1,
X is a single bond, O, S, or C-L^{a}-C(═O)N₃, wherein L^{a} is a single bond or a substituted or unsubstituted C1 to C5 alkylene group,
R¹ is hydrogen or a substituted or unsubstituted C1 to C10 alkyl group,
L¹ and L² are each independently a single bond, an ester group, a substituted or unsubstituted C1 to C20 alkylene group, a substituted or unsubstituted C6 to C30 arylene group, or a combination thereof,
n1 and n2 each independently represent an integer of 0 to 5,
n1+n2 is greater than or equal to 1,
if n1 is 2 or more, each L¹ is the same or different from each other,
if n2 is 2 or more, each L² is the same or different from each other, and
* represents a linking point.

For example, the compound may include at least one of the structural units represented by at least one of Chemical Formula 1-1, Chemical Formula 1-2, or Chemical Formula 1-3.

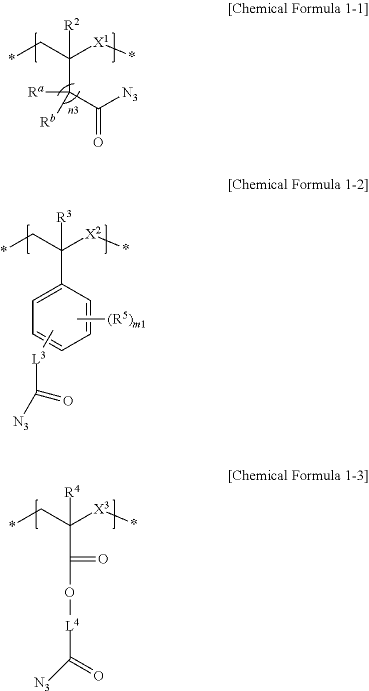

In Chemical Formula 1-1 to Chemical Formula 1-3,
X¹ to X³ are each independently a single bond, O, S, or C-L^{a}-C(═O)N₃, L^{a} is a single bond or a substituted or unsubstituted C1 to C5 alkylene group,
R^{a}, R^{b}, and R² to R⁴ are each independently hydrogen or a substituted or unsubstituted C1 to C10 alkyl group,
R⁵ is hydrogen, a halogen, a hydroxy group, a substituted or unsubstituted C1 to C10 alkyl group, or a combination thereof,
L³ and L⁴ are each independently a single bond, a substituted or unsubstituted C1 to C20 alkylene group, a substituted or unsubstituted C6 to C30 arylene group, or a combination thereof, m1 represents an integer between 1 to 4,
n3 represents an integer between 1 to 5,
if m1 is 2 or more, each R⁵ is the same or different from each other,
if n3 is 2 or more, each R^{a} is the same or different from each other,
if n3 is 2 or more, each R^{b} is the same or different from each other, and
* represents a linking point.

As a specific example, the compound may include at least one of the structural units represented by Chemical Formula 1-1a, Chemical Formula 1-2a, Chemical Formula 1-3a, Chemical Formula 1-1b, Chemical Formula 1-2b, and Chemical Formula 1-3b.

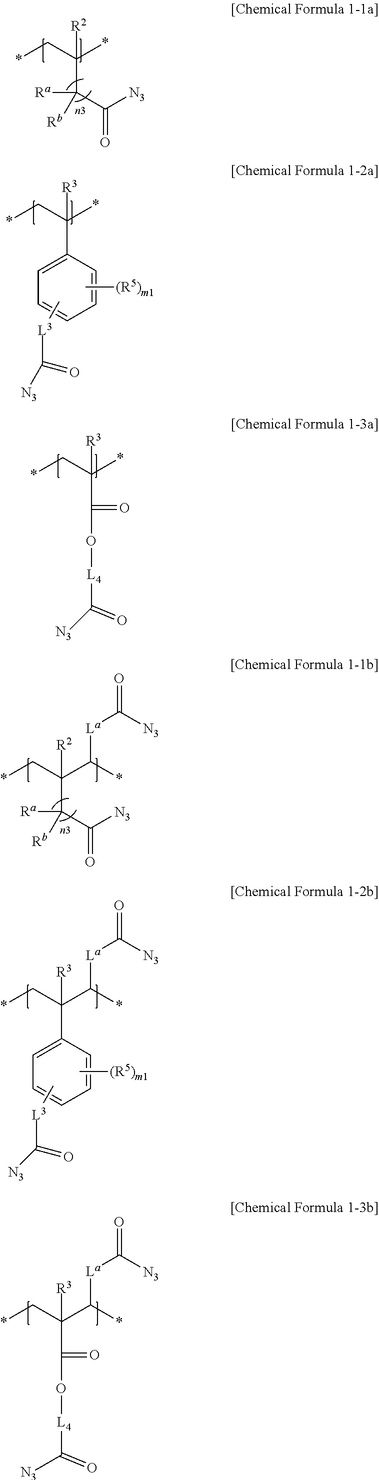

In Chemical Formula 1-1a, Chemical Formula 1-2a, Chemical Formula 1-3a, Chemical Formula 1-1b, Chemical Formula 1-2b, and Chemical Formula 1-3b,
R² to R⁴ are each independently hydrogen or a methyl group,
R^{a} and R^{b} are each independently hydrogen or a substituted or unsubstituted C1 to C10 alkyl group,
R⁵ is hydrogen, a halogen, a hydroxy group, a substituted or unsubstituted C1 to C10 alkyl group, or a combination thereof,
L^{a} is a single bond or a substituted or unsubstituted C1 to C5 alkylene group,
L³ and L⁴ are each independently a single bond, a substituted or unsubstituted C1 to C20 alkylene group, a substituted or unsubstituted C6 to C30 arylene group, or a combination thereof,
m1 represents an integer between 1 to 4,
n3 represents an integer between 1 to 5,
if m1 is 2 or more, each R⁵ is the same or different from each other,
if n3 is 2 or more, each R^{a} is the same or different from each other,
if n3 is 2 or more, each R^{b} is the same or different from each other, and
* represents a linking point.

The compound may be selected without limitation from a monomer, an oligomer, a polymer, or a combination thereof as long as it is configured to form a film within the photoresist layer.

From the perspective of forming a film, for example the compound may be a polymer.

For example, the polymer may be a homopolymer, a block copolymer, a random copolymer, or a combination thereof.

The structural unit including at least one acyl azide functional group may be included in an amount of about 1 to about 100 mol %, specifically about 20 to about 100 mol %, and more specifically about 30 to about 100 mol % based on 100 mol % of the polymer.

For example, the weight average molecular weight of the polymer may be about 1,000 to about 100,000, about 1,000 to about 50,000, and/or about 2,000 to about 15,000.

Meanwhile, as described later, the acyl azide functional group of the polymer is configured to generate isocyanate (through a Curtius rearrangement reaction) upon exposure and reacts with water (the main component of the developer) upon development to generate a primary amine functional group. Therefore, development is possible with an acidic developer due to the primary amine functional group included in the exposed region, thereby ensuring superior developability.

The solvent included in the semiconductor resist composition may be an organic solvent. For example, the organic solvent may be alkylene glycol monoalkyl ether carboxylate, alkylene glycol monoalkyl ether, lactic acid alkyl ester, alkoxypropionic acid alkyl, cyclic lactone (desirably having 4 to 10 carbon atoms), a monoketone compound which may have a ring (desirably having 4 to 10 carbon atoms), alkylene carbonate, alkyl alkoxy acetic acid, alkyl pyruvate, or a combination thereof. For example, the solvent may be a mixed solvent including a solvent having a hydroxyl group in the structure and a solvent not having a hydroxyl group may be used.

As the solvent having the hydroxyl group and the solvent not having a hydroxyl group, the example compounds described above may be appropriately selected. The solvent having the hydroxyl group may be alkylene glycol monoalkyl ether, alkyl lactate, etc., and more specifically, propylene glycol monomethyl ether (PGME), propylene glycol monoethyl ether (PGEE), methyl 2-hydroxyisobutyrate, ethyl lactate, etc. In addition, the solvent not having the hydroxyl group may be alkylene glycol monoalkyl ether acetate, alkyl alkoxy propionate, a monoketone compound which may have a ring, a cyclic lactone, or an alkyl acetate, and more specifically, propylene glycol monomethyl ether acetate (PGMEA), ethyl ethoxypropionate (specifically, ethyl 3-ethoxypropionate), 2-heptanone, γ-butyrolactone, cyclohexanone, cyclopentanone, 3-methoxybutyl acetate, or butyl acetate, and for example, propylene glycol monomethyl ether acetate, γ-butyrolactone, ethyl ethoxypropionate, cyclohexanone, cyclopentanone, or 2-heptanone, etc. Examples of the solvent not having the hydroxyl group may include propylene carbonate.

As a most specific example, the solvent may include propylene glycol monomethyl ether acetate. A sole solvent of propylene glycol monomethyl ether acetate, or a mixed solvent of two or more types including propylene glycol monomethyl ether acetate may be used, but the present disclosure is not limited thereto.

The solvent may be included as a balance amount in the semiconductor photoresist composition, and specifically may be included in an amount of about 65 wt % to about 99 wt %, for example, about 70 wt % to about 99 wt %, for example, about 75 wt % to about 98 wt %. If included within the content range, the semiconductor photoresist composition can have appropriate coating properties.

In addition, the semiconductor photoresist composition may further include a silane coupling agent as an adherence enhancer in order to improve a close-contacting force with the substrate (e.g., in order to improve adherence of the semiconductor photoresist composition to the substrate). The silane coupling agent may be for example a silane compound including a carbon-carbon unsaturated bond such as vinyltrimethoxysilane, vinyl triethoxysilane, vinyl trichlorosilane, vinyl tris(β-methoxyethoxy)silane; or 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyl diethoxysilane; trimethoxy[3-(phenylamino)propyl]silane, and the like, but is not limited thereto.

According to some example embodiments, a method of forming patterns using the aforementioned semiconductor photoresist composition is provided. For example, the manufactured pattern may be a photoresist pattern.

The method of forming patterns according to some example embodiments includes forming an etching-objective layer on a substrate; coating the semiconductor photoresist composition on the etching-objective layer to form a photoresist layer; exposing and developing the photoresist layer to form a photoresist layer having a photoresist pattern formed thereon; and etching the etching-objective layer using the photoresist pattern as an etching mask.

The semiconductor photoresist composition includes a compound including a structural unit including at least one acyl azide functional group; and a solvent.

The semiconductor photoresist composition may be a composition for a non-chemically amplified (Non-CAR) photoresist.

The semiconductor photoresist composition may be a positive photoresist composition.

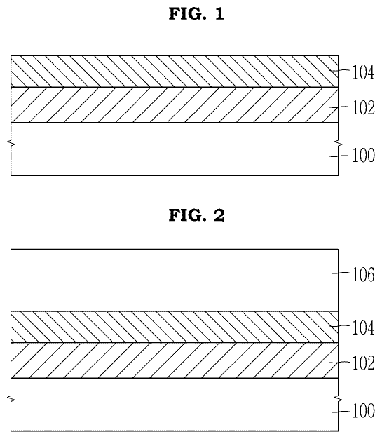

Hereinafter, a method of forming patterns using the semiconductor photoresist composition is described referring to FIGS. 1 to 5. FIGS. 1 to 5 are cross-sectional views for explaining a method of forming patterns using a semiconductor photoresist composition according to some example embodiments.

Referring to FIG. 1, an object for etching is prepared. The object for etching may be a thin film 102 formed on a semiconductor substrate 100. Hereinafter, the object for etching is limited to the thin film 102. A surface of the thin film 102 is washed to remove impurities and/or the like remaining thereon. The thin film 102 may be for example a silicon nitride layer, a polysilicon layer, a silicon oxide layer, etc.

Subsequently, the resist underlayer composition for forming a resist underlayer 104 is spin-coated on the surface of the washed thin film 102. However, the embodiments are not limited thereto, and known various coating methods (for example chemical vapor deposition method (CVD), a spray coating, a dip coating, a knife edge coating, a printing method, for example an inkjet printing and a screen printing, and/or the like) may be used.

In at least some embodiments, the coating process of the resist underlayer may be omitted.

Then, the coated composition is dried and baked to form a resist underlayer 104 on the thin film 102. The baking may be performed at about 100° C. to about 500° C., for example, about 100° C. to about 300° C.

The resist underlayer 104 is formed between the substrate 100 and a photoresist layer 106 and thus may prevent and/or reduce non-uniformity and pattern formability of a photoresist line width when a ray reflected from on the interface between the substrate 100 and the photoresist layer 106 or a hardmask between layers is scattered into an unintended photoresist region.

Referring to FIG. 2, the photoresist layer 106 is formed by coating the semiconductor photoresist composition on the resist underlayer 104. The photoresist layer 106 is obtained by coating the aforementioned semiconductor photoresist composition on the thin film 102 formed on the substrate 100 and then, curing it through a heat treatment.

More specifically, the formation of a pattern by using the semiconductor photoresist composition may include coating the semiconductor resist composition on the substrate 100 having the thin film 102 through spin coating, slit coating, inkjet printing, and/or the like and then, drying it to form the photoresist layer 106.

The semiconductor photoresist composition has already been described in detail and therefore will not be illustrated again.

Subsequently, a substrate 100 having the photoresist layer 106 is subjected to a first baking process (prebake: PB). The first baking process may be performed at about 80° C. to about 120° C.

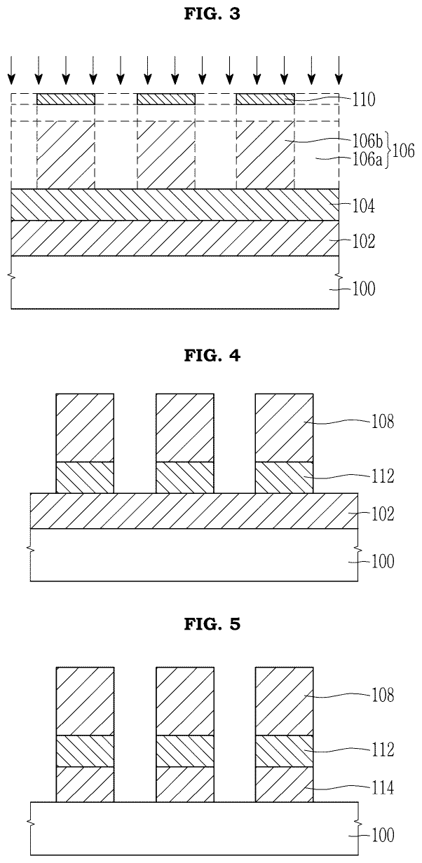

Referring to FIG. 3, the photoresist layer 106 may be selectively exposed using a patterned mask 110.

For example, the exposure may use an activation radiation with light having a high energy wavelength such as EUV (extreme ultraviolet; a wavelength of about 13.5 nm), an E-Beam (an electron beam), and/or the like; as well as light having a lower wavelength such as an i-line (a wavelength of about 365 nm), a KrF excimer laser (a wavelength of about 248 nm), an ArF excimer laser (a wavelength of about 193 nm), and/or the like.

More specifically, the activation radiation may be ultraviolet light with a wavelength range of about 10 nm to about 300 nm, for example, a KrF excimer laser (about 248 nm), an ArF excimer laser (about 193 nm), an F2 excimer laser (about 157 nm), an Extreme EUV (about 13.5 nm), etc.

The resist composition of the present invention may be desirably used to form a resist film that is exposed to light with a wavelength of about 250 nm or less.

The exposed region 106a of the photoresist layer 106 (e.g., the region not covered by the patterned hard mask 110) changes in the characteristic of being soluble in a developer, and thus has a different solubility from the unexposed region 106b of the photoresist layer 106.

That is, in the exposure step, the acyl azide functional group of the compound (or polymer) including the structural unit including at least one acyl azide functional group included in the semiconductor photoresist composition undergoes a Curtius rearrangement reaction as illustrated in the schematic diagram of Diagram 1.

Referring to Diagram 1, isocyanate is generated as N₂ is generated from the acyl azide functional group in the exposure step. Next, the isocyanate reacts with water in the developing step to generate CO₂ and produce a primary amine, thereby changing the polarity of the compound included in the exposed area from neutral to basic.

In FIG. 4, a photoresist pattern 108 formed by dissolving and removing portions of the photoresist layer 106 corresponding to the exposed region 106a using a developer is illustrated.

For example, the developer may be an acidic aqueous solution.

As the acyl azide functional group of the compound changes into an amine functional group, the polarity of the exposed region changes from neutral to alkaline, and the region that has changed into alkaline during the exposure and development steps may be removed by an acidic aqueous solution.

The pH of the above acidic aqueous solution can be between −10 and 1.

For example, the acidic aqueous solution may be at least one selected from a hydrochloric acid (HCl) aqueous solution, a sulfuric acid (H2SO4) aqueous solution, a nitric acid (HNO3) aqueous solution, a hydrobromic acid (HBr) aqueous solution, a hydroiodic acid (HI) aqueous solution, a perchloric acid (HClO4) aqueous solution, a chloric acid (HClO3) aqueous solution, a fluorosulfonic acid (FSO3H) aqueous solution, a trifluoroacetic acid (CF3CO2H) aqueous solution, and a trifluoromethanesulfonic acid (CF3SO3H) aqueous solution, which are strong acids having a pKa of 2 or lower, etc.

The acid concentration of the acidic aqueous solution may be about 0.1 to about 20 wt %.

The acidic aqueous solutions may be used alone or in combination.

In general, in a chemically amplified photoresist composition, a chemical bond decomposition reaction may be induced in the acid-reactive functional group of the polymer by an acid diffusion reaction caused by the catalytic action of a photoacid generator, and accordingly, the exposed region becomes easily soluble in an alkaline developer, so that a positive tone photoresist can be implemented in which the exposed region is removed in the developing step.

However, the photoresist pattern according to the present disclosure is implemented as a positive tone photoresist by a non-chemically amplified photoresist composition as described above.

The detailed description is as shown in FIG. 6A and FIG. 6B.

When a pattern is formed by a chemically amplified photoresist composition, an alkaline developer is applied in the development step. When a representative example of the alkaline developer applied at this time is TMAH, as explained in the schematic diagram of FIG. 6A, since the volume of the cation of the alkaline chemical species to be ion-exchanged (e.g., the tetramethyl ammonium cation of TMAH) is large, a degree of swelling increases (B), so that the critical dimension uniformity (CDU) on the substrate deteriorates, the occurrence of defects increases, and this may result in a decrease in resolution.

On the other hand, when forming a pattern by the non-chemically amplified photoresist composition according to the present invention, an acidic developer is applied in the developing step, and in this case, as a representative example of the acidic developer to be applied, in the case of HCl or H₂SO₄, as explained in the schematic diagram of FIG. 6B, the volume of the anion of the acidic chemical species to be ion-exchanged (e.g., Cl— of HCl, SO₄— of H₂SO₄, etc.) is smaller than that of the tetramethyl ammonium cation, so that a degree of swelling is relatively reduced (C), and thus the critical dimension uniformity (CDU) on the substrate may be improved, the occurrence of defects may be reduced, and resolution characteristics may be enhanced.

Subsequently, the photoresist pattern 108 is used as an etching mask to etch the resist underlayer 104. Through this etching process, an organic layer pattern 112 is formed. The organic layer pattern 112 also may have a width corresponding to that of the photoresist pattern 108.

Referring to FIG. 5, the exposed thin film 102 is etched by applying the photoresist pattern 108 as an etching mask. As a result, the thin film is formed as a thin film pattern 114.

The etching of the thin film 102 may be for example dry etching using an etching gas and the etching gas may be for example CHF3, CF4, Cl2, BCl3 and a mixed gas thereof, but is not limited thereto.

Hereinafter, the present disclosure will be described in more detail through examples of the preparation of the aforementioned semiconductor photoresist composition. However, the present disclosure is technically not restricted by the following examples.

### Synthesis of Polymers

### Synthesis Example 1: Synthesis of Polymer (or Compound) 1

Polymer 1 represented by Chemical Formula 1A and having a weight average molecular weight of 4,700 g/mol was synthesized from poly(acrylic acid) having a molecular weight (Mw) of 3,000 (catalog number: ACM9003014-21), which was available from Alfa-Chemistry, by referring to a synthesis method described in ‘1-N-ACYLAMINO-1,3-DIENES FROM 2,4-PENTADIENOIC ACIDS BY THE CURTIUS REARRANGEMENT: BENZYL trans-1,3-BUTADIENE-1-CARBAMATE’ (Org. Synth. 1979, 59, 1 (DOI: 10.15227/orgsyn.059.0001)).

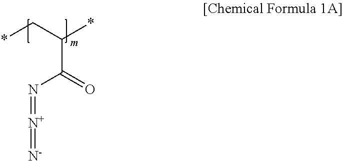

### Synthesis Example 2: Synthesis of Polymer (or Compound) 2

Polymer 2 represented by Chemical Formula 1B and having a weight average molecular weight of 3,500 g/mol was synthesized from poly(acrylic acid-co-maleic acid) (m:n=1:1 in a mole ratio) having a molecular weight (Mw) of 3,000 (catalog number: 416053), which was available from Merck &Co., Inc., by referring to a synthesis method described in ‘1-N-ACYLAMINO-1,3-DIENES FROM 2,4-PENTADIENOIC ACIDS BY THE CURTIUS REARRANGEMENT: BENZYL trans-1,3-BUTADIENE-1-CARBAMATE’ (Org. Synth. 1979, 59, 1 (DOI: 10.15227/orgsyn.059.0001)).

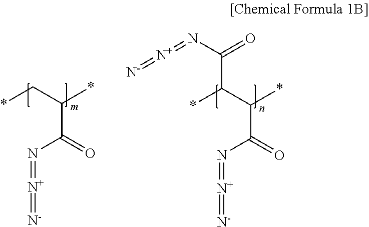

### Synthesis Example 3: Synthesis of Polymer (or Compound) 3

Polymer 3 represented by Chemical Formula 1C and having a weight average molecular weight of 5,200 g/mol was synthesized from poly(4-vinylbenzoic acid) (Product ID: P7137-VBA) having a molecular weight (Mn) of 4,300 and PDI (Mw/Mn) of 1.3, which was available from Polymer Source, Inc., by referring to a synthesis method described in ‘1-N-ACYLAMINO-1,3-DIENES FROM 2,4-PENTADIENOIC ACIDS BY THE CURTIUS REARRANGEMENT: BENZYL trans-1,3-BUTADIENE-1-CARBAMATE’ (Org. Synth. 1979, 59, 1 (DOI: 10.15227/orgsyn.059.0001)).

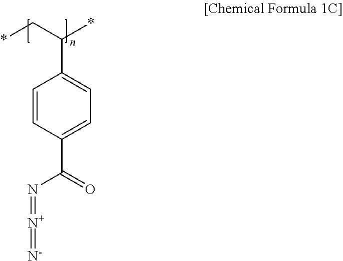

### Comparative Synthesis Example 1: Synthesis of Polymer 1D

Polymer 1D (Mw: 5,000) including structural units M-1 and M-2 in each content of 50 mol % was obtained as white powder by referring to Korean Patent 10-2022-0163277.

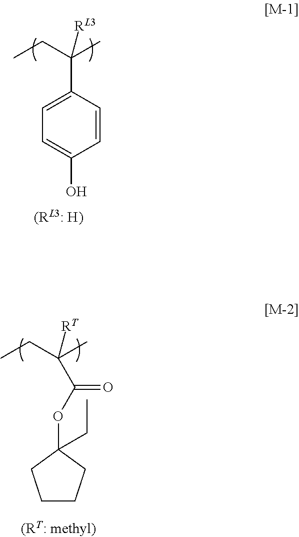

### Preparation of Photoresist Compositions

### Examples 1 to 3

Each of the polymers according to Synthesis Examples 1 to 3 was mixed with a mixed solvent of PGMEA (propylene glycol monomethylether acetate) and PGME (propylene glycol monomethylether) as a solvent in a weight ratio described in Table 1 and then, filtered through a membrane filter with a hole diameter of 0.2 μm to prepare a composition for a photoresist.

TABLE 1
(unit: wt %)

| | | Example 1 | Example 2 | Example 3 |
|---|---|---|---|---|
| Polymer | Chemical | 3 | 0 | 0 |
| | Formula 1A | | | |
| | Chemical | 0 | 3 | 0 |
| | Formula 1B | | | |
| | Chemical | 0 | 0 | 3 |
| | Formula 1C | | | |

| | | | |
|---|---|---|---|
| PGMEA | 48.5 | 48.5 | 48.5 |
| PGME | 48.5 | 48.5 | 48.5 |

### Comparative Example 1

Polymer 1D of Comparative Synthesis Example 1: Photoacid generator B-1: Acid diffusion controller C-2 were mixed in a weight ratio of 100:50:20, and the mixture was added at 3 wt % to an organic solvent of PGMEA and PGME mixed in a weight ratio of 1:1 and then, filtered through a 0.1 μm PTFE (polytetrafluoroethylene) syringe filter to prepare a composition for a photoresist.

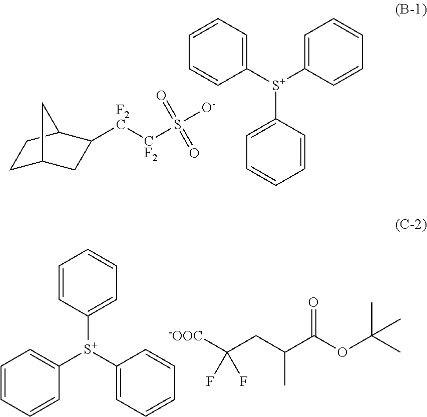

### (Evaluation)

### Formation of Photoresist Pattern

A circular silicon wafer having a 12-inch diameter was used as a substrate in each of the examples, and a photoresist thin film was formed by spin-coating 5 milliliters (mL) of hexamethyldisilazane on the substrate and firing at 150° C. for 60 seconds, and then, the semiconductor photoresist compositions according to Examples 1 to 3 and Comparative Example 1 was spin-coated onto each of the examples at 1500 rpm for 30 seconds and fired (post-apply baking, PAB) at 100° C. for 60 seconds. After the coating and baking, the photoresist thin films were measured with respect to a thickness through ellipsometry, wherein the measured thickness was about 60 nm. This thin film was exposed to light using an EUV exposure apparatus (NXE3600, ASML) having NA=0.33, a conventional illumination system (s=0.5), and a 45 nm pitch contact hole pattern mask.

After the exposure, only for Comparative Example 1, which was a chemically amplified photoresist composition, post-exposure baking (PEB) was performed at 120° C. for 60 seconds. Subsequently, the EUV pattern exposed photoresist thin films of Examples 1 to 3 were developed by using a 2 mass % hydrochloric acid aqueous solution, but the film of Comparative Example 1 was alkali-developed by using a 2.38 mass % TMAH aqueous solution. All the wafers were washed with water after the development and then, dried to form positive photoresist patterns (45 nm pitch contact holes).

The photoresist patterns obtained by using the photoresist compositions were measured with respect to sensitivity (dose-to-size, Eop) and critical dimension uniformity (CDU) by using a critical dimension measurement scanning electron microscope (CD-SEM), CG-5600 made by Hitachi High-Tech. The results are shown in Table 2.

### Evaluation 1: Sensitivity Measurement

As for the photoresist patterns obtained by using the photoresist compositions, an exposure dose for forming the 45 nm pitch contact hole patterns was set as an optimal exposure dose, which was Eop (‘exposer’, unit: mJ/cm²).

### Evaluation 2: Evaluation of Critical Dimension Uniformity (CDU) Performance

After forming the 45 nm pitch contact hole patterns by irradiating the exposure dose of Eop, which was determined in the sensitivity evaluation, the hole patterns were measured with respect to a size on the top of the patterns by using the CD-SEM measurement equipment. A total of 20,000 hole CDs were measured to obtain a measurement distribution, from which 3-sigma was obtained and expressed as CDU (unit: nm). The smaller CDU, the less variation in the contact hole size, which confirms better quality patterning.

TABLE 2

| | Eop | CDU |
|---|---|---|
| | (mJ/cm²) | (nm) |
| Example 1 | 71 | 3.2 |
| Example 2 | 65 | 3.6 |
| Example 3 | 80 | 2.8 |
| Comparative | 75 | >5.0 |
| Example 1 | | |

Referring to the results of Table 2, the semiconductor photoresist compositions according to Examples 1 to 3, compared with the semiconductor photoresist composition according to Comparative Example 1, exhibited much more excellent critical dimension uniformity (CDU) as well as maintained equal or higher sensitivity.

Herein, example embodiments of the present disclosure have been described and illustrated; however, it is apparent to a person with ordinary skill in the art that the present disclosure is not limited to the embodiment as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims of the present disclosure.

What is claimed is:

1. A semiconductor photoresist composition, comprising:
a compound including at least one structural unit including an acyl azide functional group; and
a solvent.

2. The semiconductor photoresist composition of claim 1, wherein
the structural unit is represented by Chemical Formula 1: 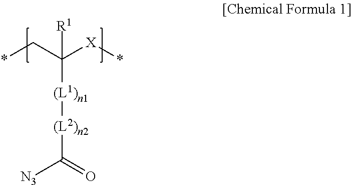
wherein, in Chemical Formula 1,
X is a single bond, O, S, or C-L^{a}-C(═O)N₃,
R¹ is hydrogen or a substituted or unsubstituted C1 to C10 alkyl group,
L¹ and L² are each independently a single bond, an ester group, a substituted or unsubstituted C1 to C20 alkylene group, a substituted or unsubstituted C6 to C30 arylene group, or a combination thereof,
L^{a} is a single bond, or a substituted or unsubstituted C1 to C5 alkylene group,
n1 and n2 each independently represent an integer between 0 to 5,
n1+n2 is greater than or equal to 1, and
* represents a linking point.

3. The semiconductor photoresist composition of claim 1, wherein
the at least one structural unit is represented by at least one of Chemical Formula 1-1, Chemical Formula 1-2, and Chemical Formula 1-3: 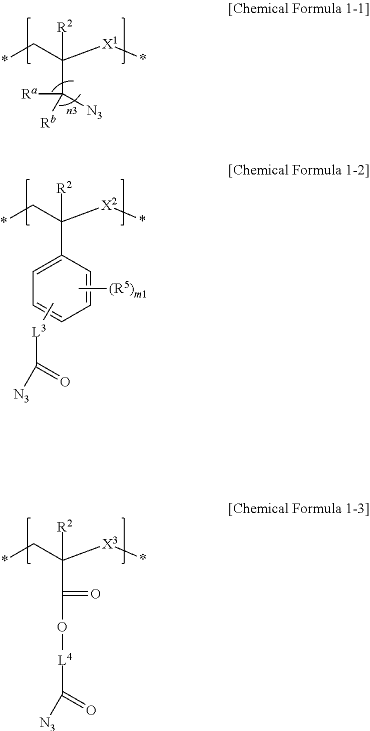
wherein, in Chemical Formula 1-1 to Chemical Formula 1-3,
X¹ to X³ are each independently a single bond, O, S, or C-L^{a}-C(═O)N₃,
R^{a}, R^{b}, and R² to R⁴ are each independently hydrogen or a substituted or unsubstituted C1 to C10 alkyl group,
R⁵ is hydrogen, a halogen, a hydroxy group, a substituted or unsubstituted C1 to C10 alkyl group, or a combination thereof,
L^{a} is a single bond or a substituted or unsubstituted C1 to C5 alkylene group,
L³ and L⁴ are each independently a single bond, a substituted or unsubstituted C1 to C20 alkylene group, a substituted or unsubstituted C6 to C30 arylene group, or a combination thereof,
m1 represents an integer between 1 to 4,
n3 represents an integer between 1 to 5, and
* represents a linking point.

4. The semiconductor photoresist composition of claim 1, wherein
the at least one structural unit is represented by at least one of Chemical Formula 1-1a, Chemical Formula 1-2a, Chemical Formula 1-3a, Chemical Formula 1-1b, Chemical Formula 1-2b, and Chemical Formula 1-3b: 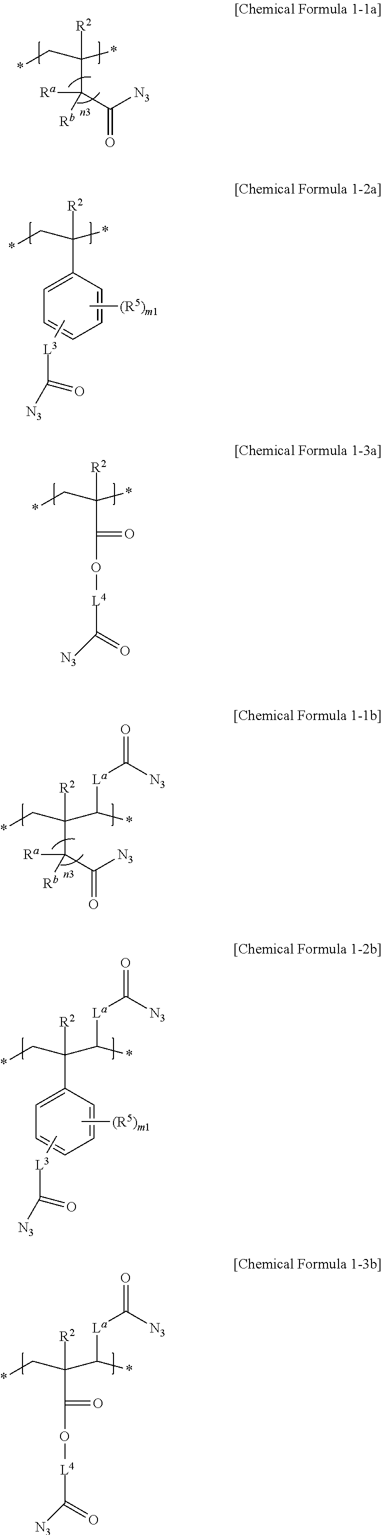
wherein, in Chemical Formula 1-1a, Chemical Formula 1-2a, Chemical Formula 1-3a, Chemical Formula 1-1b, Chemical Formula 1-2b and Chemical Formula 1-3b,
R² to R⁴ are each independently hydrogen or a methyl group,
R^{a} and R^{b} are each independently hydrogen or a substituted or unsubstituted C1 to C10 alkyl group,
R⁵ is hydrogen, a halogen, a hydroxy group, a substituted or unsubstituted C1 to C10 alkyl group, or a combination thereof,
L^{a} is a single bond or a substituted or unsubstituted C1 to C5 alkylene group,
L³ and L⁴ are each independently a single bond, a substituted or unsubstituted C1 to C20 alkylene group, a substituted or unsubstituted C6 to C30 arylene group, or a combination thereof,
m1 represents an integer between 1 to 4,
n3 represents an integer between 1 to 5, and
* represents a linking point.

5. The semiconductor photoresist composition of claim 1, wherein
the compound is a monomer, an oligomer, a polymer, or a combination thereof.

6. The semiconductor photoresist composition of claim 5, wherein the compound includes the polymer, and
the polymer is a homopolymer, a block copolymer, a random copolymer, or a combination thereof.

7. The semiconductor photoresist composition of claim 5, wherein the compound includes the polymer, and
the structural unit including at least one acyl azide functional group is included in an amount of about 1 mol % to about 100 mol % based on 100 mol % of the polymer.

8. The semiconductor photoresist composition of claim 5, wherein the compound includes the polymer, and
a weight average molecular weight of the polymer is about 1,000 to about 100,000.

9. A method of forming patterns, comprising
forming an etching-objective layer on a substrate;
forming a photoresist layer by coating a semiconductor photoresist composition on the etching-objective layer;
forming a photoresist pattern in the photoresist layer by exposing and developing the photoresist layer; and
etching the etching-objective layer using the photoresist pattern as an etching mask,
wherein the semiconductor photoresist composition comprises a solvent and a compound including a structural unit including at least one acyl azide functional group.

10. The method of claim 9, wherein the semiconductor photoresist composition is configured as a composition for non-chemically amplified (Non-CAR) photoresist.

11. The method of claim 9, wherein the semiconductor photoresist composition is a positive photoresist composition.

12. The method of claim 9, wherein in the exposing of the photoresist layer, the compound including the structural unit including at least one acyl azide functional group undergoes a Curtius rearrangement reaction.

13. The method of claim 12, wherein the Curtius rearrangement reaction includes generating an isocyanate from the acyl azide functional group.

14. The method of claim 13, wherein the developing of the photoresist layer includes generating a primary amine by reacting the isocyanate with water.

15. The method of claim 14, wherein the exposing and developing of the photoresist layer includes changing an exposed region of the photoresist layer from a neutral pH to a basic pH.

16. The method of claim 9, wherein the developing is performed with an acidic aqueous solution.

17. The method of claim 16, wherein the acidic aqueous solution includes at least one of a hydrochloric acid (HCl) aqueous solution, a sulfuric acid (H₂SO₄) aqueous solution, a nitric acid (HNO₃) aqueous solution, a hydrobromic acid (HBr) aqueous solution, a hydroiodic acid (HI) aqueous solution, a perchloric acid (HClO₄) aqueous solution, a chloric acid (HClO₃) aqueous solution, a fluorosulfonic acid (FSO₃H) aqueous solution, a trifluoroacetic acid (CF₃CO₂H) aqueous solution, or a trifluoromethanesulfonic acid (CF₃SO₃H) aqueous solution.

18. The method of claim 16, wherein an acid concentration of the acidic aqueous solution is about 0.1 wt % to about 20 wt %.

19. The method of claim 9, wherein the exposing the photoresist layer includes radiating a light with a wavelength of about 10 nm to about 300 nm to the photoresist layer.

20. The method of claim 9 further comprising:
forming a resist underlayer between the substrate and the photoresist layer.
